(19) United States
(12) Patent Application Publication
(10) Pub. No.: US 2004/0171272 A1
(43) Pub. Date: Sep. 2, 2004

(54) Method of etching metallic materials to form a tapered profile

(75) Inventors: Guangxiang Jin, San Jose, CA (US); Padmapani C. Nallan, San Jose, CA (US); Chun Yan, San Jose, CA (US); Ajay Kumar, Sunnyvale, CA (US)

Correspondence Address: Patent Counsel, Applied Materials, Inc., P.O. Box 450A, Santa Clara, CA, 95052, US

(73) Assignee: Applied Materials, Inc.

(21) Appl. No.: 10/377,852

(22) Filed: Feb. 28, 2003

(51) Int. Cl. H01L 21/302; H01L 21/461

(52) U.S. Cl. 438/708

(57) ABSTRACT

A method of fabricating a structure having a tapered profile using a low temperature plasma etch (LTPE) process. In one embodiment, the LTPE process uses a gas comprising carbon tetrafluoride (CF₄), trifluoromethane (CHF₃), and nitrogen (N₂) to fabricate the structure from a material layer of at least one of tantalum (Ta), tantalum nitride (TaN), and the like.

### BACKGROUND OF THE INVENTION

1. Field of the Invention

The present invention generally relates to a method of etching material. More specifically, the present invention relates to a method of etching a metallic material to form a tapered profile.

2. Description of the Related Art

Microelectronic devices are generally fabricated on a semiconductor substrate as integrated circuits wherein various conductive layers are interconnected to one another to facilitate propagation of electronic signals within the device. An example of such a device is a storage element in magneto-resistive random access memories (MRAM) that facilitate storage of digital information in a form of the direction of magnetization of a magnetic material within the MRAM.

A memory cell in a MRAM device is a multi-layered structure comprising a pair of magnetic layers that are separated by a tunnel layer of a non-magnetic dielectric material, such as aluminum oxide (Al₂O₃) and the like. The magnetic layers may each comprise a plurality of films of magnetic materials, e.g., permalloy (NiFe), cobalt iron (CoFe), and the like. The magnetic layers are supplied with film electrodes that form an electrical connection for the memory cell to the lines of the MRAM. Such electrodes may be formed from, e.g., tantalum (Ta), tantalum nitride (TaN), and the like.

Fabrication of MRAM devices comprises etch processes in which one or more layers comprising a MRAM film stack are removed, either partially or in total. During such etch processes, the top electrode (e.g., Ta or TaN electrode) is generally used as an etch mask for the underlying layers of the film stack. The MRAM film stack comprises the layers of materials that may leave difficult to remove conductive post-etch residues. The conductive residues may cause electrical short-circuits within the MRAM device.

It has been noticed that the amount of conductive residues is minimal when the etch mask has sidewalls that are sloped (i.e., the top electrode has a tapered profile) at an angle that is not greater than 75°. However, a conventional process of fabricating the top electrode of the MRAM film stack cannot fabricate such a mask profile.

Therefore, there is a need in the art for a method of etching a metallic material to form a tapered profile such that the etched material can be used as a mask having a tapered profile.

### SUMMARY OF THE INVENTION

The invention is a method of etching a metallic material using a low temperature plasma etch (LTPE) process to form a structure having a tapered profile. In one embodiment, the LTPE process uses a gas comprising carbon tetrafluoride (CF₄), trifluoromethane (CHF₃), and nitrogen (N₂) to fabricate the mask from a material layer of at least one of tantalum (Ta), tantalum nitride (TaN), and the like while the substrate is maintained at a temperature of about 50° C. or less. In one exemplary application, such structure is used during fabrication of magneto-resistive random access memories (MRAM) devices.

### BRIEF DESCRIPTION OF THE DRAWINGS

The teachings of the present invention can be readily understood by considering the following detailed description in conjunction with the accompanying drawings, in which:

FIG. 1 depicts a flow diagram of a method of fabricating a structure having a tapered profile in accordance with of the present invention;

FIGS. 2A-2E, together, depict a sequence of schematic, cross-sectional views of a substrate comprising a structure having a tapered profile being formed in accordance with the method of FIG. 1;

FIG. 3 depicts a schematic diagram of an exemplary plasma processing apparatus of the kind used in performing portions of the inventive method; and

FIG. 4 is a table summarizing the processing parameters of one embodiment of the inventive method when practiced using the apparatus of FIG. 3.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention is a method of etching a metallic material to form a structure having a tapered profile (i.e., a structure having sloped sidewalls) using a low temperature plasma etch (LTPE) process. The structure is generally used as an etch mask that can reduce the amount of post-etch residue. Such structure may also be used as a functional element (e.g., conductor) of the integrated circuit.

In one exemplary application, the method is used to fabricate a metallic etch mask having sidewalls that are sloped at an angle that is not greater than 75°. During fabrication of a MRAM device, such a mask profile decreases the amount of post-etch residue, as well as may be used as an electrode in the MRAM device being fabricated.

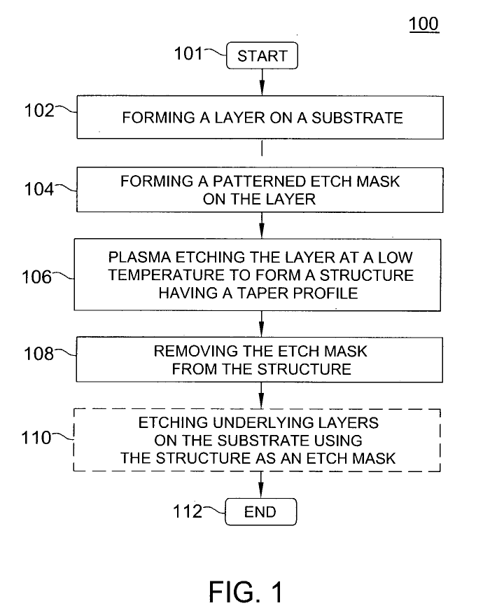

FIG. 1 depicts a flow diagram of a method 100 of fabricating a structure having a tapered profile in accordance with the present invention. The method 100 illustratively comprises processes that are performed upon a MRAM film stack.

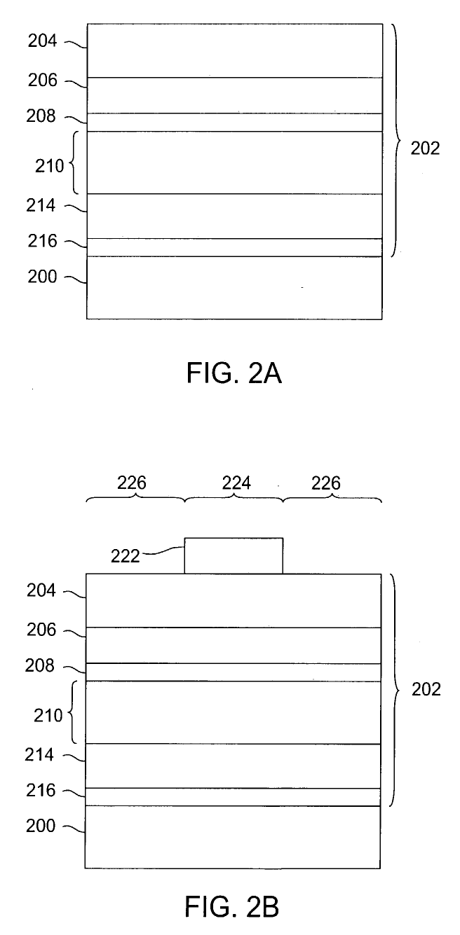

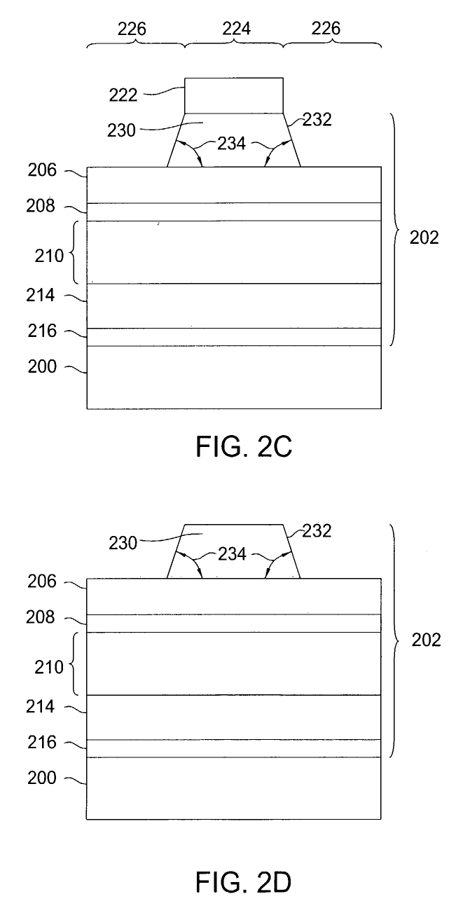

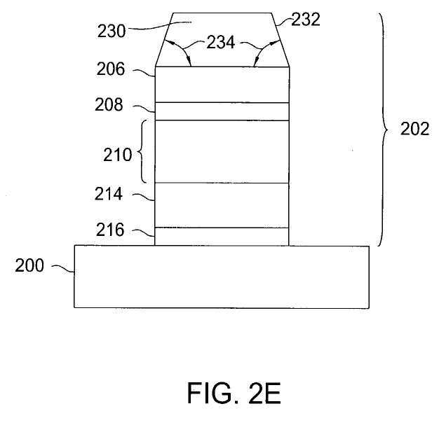

FIGS. 2A-2E, together, depict a sequence of schematic, cross-sectional views of a substrate comprising a structure having a tapered profile being formed in accordance with the method 100 of FIG. 1. The cross-sectional views in FIGS. 2A-2E relate to processing steps that are used to form the structure. Conventional sub-processes (e.g., exposure and development of photoresist, wafer cleaning procedures, and the like) are well known in the art and, as such, are not shown in FIG. 1 and FIGS. 2A-2E. The images in FIGS. 2A-2E are not depicted to scale and are simplified for illustrative purposes.

The method 100 starts at step 101 and proceeds to step 102, when a MRAM film stack 202 is formed on a substrate (e.g., silicon (Si) wafer) 200 (FIG. 2A). In one embodiment, the MRAM film stack 202 comprises a top electrode layer 204, a free magnetic layer 206, a tunnel layer 208, a multi-layer magnetic stack 210, a bottom electrode layer 214, and a barrier layer 216.

In one exemplary embodiment, the top electrode 204 and bottom electrode layer 214 are each formed from at least one of film of a conductive material (e.g., tantalum (Ta), tantalum nitride (TaN), and the like). The free magnetic layer 206 generally comprises a film of nickel-iron (NiFe) alloy. Alternatively, the free magnetic layer 206 may also comprise at least one film of another magnetic material (e.g., cobalt-iron (CoFe) alloy and the like) that is formed between the film of nickel-iron alloy and the tunnel layer 208. The tunnel layer 208 forms a magnetic tunnel junction of the MRAM device and is composed of a non-magnetic dielectric material, such as alumina (Al₂O₃) and the like. The multi-layer magnetic stack 210 generally comprises a plurality of magnetic films, such as films of CoFe, Ru, CoFe, PtMn or IrMn, NiFe, NiFeCr, and the like. The barrier layer 216 may be formed from a dielectric material (e.g., silicon dioxide (SiO₂), silicon nitride (Si₃N₄), and the like). It should be understood that, in other embodiments, the MRAM film stack 202 may comprise layers that are formed from different materials.

The layers of the MRAM film stack 202 can be formed using a conventional thin film deposition technique, such as an atomic layer deposition (ALD), a physical vapor deposition (PVD), chemical vapor deposition (CVD), plasma enhanced CVD, and the like. Fabrication of the MRAM devices may be performed using, e.g., the respective processing reactors of the CENTURA® platform, ENDURA® platform, and other semiconductor wafer processing systems available from Applied Materials, Inc. of Santa Clara, Calif.

At step 104, a mask 222 is formed on the top electrode layer 204 (FIG. 2B). The mask 222 defines location and topographic dimensions of the MRAM device being fabricated using the method 100. In the embodiment shown, the mask 222 protects the region 224 of the MRAM film stack 202 and exposes the adjacent regions 226 of the stack 202. In one exemplary embodiment, the mask 222 is a patterned photoresist mask. Such photoresist mask 222 may further comprise an anti-reflective layer (not shown) that controls a reflection of the light during exposure of the photoresist.

As feature sizes are reduced, inaccuracies in an etch mask pattern transfer process can arise from optical limitations inherent to the lithographic process, such as the light reflection. The anti-reflective layer may be composed from silicon nitride (SiN), polyamides, and the like. In some applications, the anti-reflective layer may not be necessary. As such, the anti-reflective layer is considered optional. Alternatively, the mask 222 may be composed of other materials, e.g., Advanced Patterning Film™ (APF) available from Applied Materials, Inc. of Santa Clara.

Processes of applying various etch masks are described, e.g., in commonly assigned U.S. patent application Ser. No. 10/218,244, filed Aug. 12, 2002 (Attorney docket number 7454) and Ser. No. 09/590,322, filed Jun. 8, 2000 (Attorney docket number 4227), which are incorporated herein by reference.

At step 106, the top electrode layer 204 is etched using the LTPE process (FIG. 2C). In one embodiment, step 106 forms a top electrode 230 having sidewalls 232 sloped at an angle 234 that is not greater than 75°. In this embodiment, the LTPE process uses an etchant gas comprising carbon tetrafluoride (CF₄), trifluoromethane (CHF₃), nitrogen (N₂), and an optional diluent gas, such as argon (Ar), Helium, Neon, and the like. During the LTPE process, the substrate temperature is maintained at not greater than 50 degrees Celsius, e.g., between about 0 and 50 degrees Celsius.

The etchant gas is selected to facilitate fabrication of the structure (i.e., Ta/TaN top electrode 230) having a tapered profile, as well as provide high etch selectivity to the material of the top electrode 230 over the materials of the free magnetic layer 206 and mask 222.

Step 106 uses the mask 222 (e.g., photoresist mask) as an etch mask and may use the free magnetic layer 206 as an etch stop layer (e.g., an endpoint detection system of the etch reactor may monitor plasma emissions at a particular wavelength to determine an end of the LTPE process). Specifically, during etching the Ta or TaN top electrode layer 204, the endpoint detection system may monitor plasma emissions at the wavelength of about 3630 Angstroms to determine that the top electrode layer 204 has been removed in the regions 226.

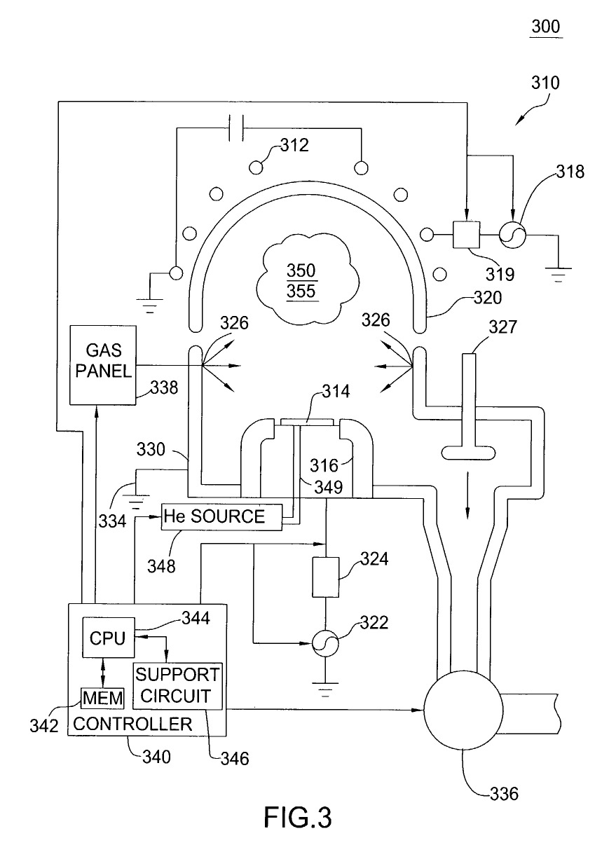

Step 106 can be performed, e.g., in a Decoupled Plasma Source (DPS) of the CENTURA® platform. The DPS reactor (described in reference to FIG. 3 below) uses an inductive source to produce a high-density plasma and a source of radio-frequency power to bias the wafer.

In one illustrative embodiment, during etching the Ta/TaN top electrode layer 204 in the DPS reactor, step 106 provides carbon tetrafluoride at a flow rate of 10 to 300 sccm and trifluoromethane at a flow rate of 5 to 100 sccm (i.e., a CF₄:CHF₃ flow ratio ranging from 1:10 to 60:1), nitrogen at a flow rate of 5 to 100 sccm (corresponds to a CHF₃:N₂ flow ratio ranging from 1:20 to 20:1), as well as argon at a flow rate of 10 to 300 sccm. Further, step 106 applies 200 to 2000 W of plasma power and 10 to 200 W of bias power, maintains a wafer temperature at about 0 to not greater than 50 degrees Celsius, and maintains a pressure in the reaction chamber at 1 to 10 mTorr.

One illustrative LTPE process provides CF₄ at a flow rate of 60 sccm, CHF₃ at a flow rate of 20 sccm (i.e., a CF₄:CHF₃ flow ratio of about 3:1), N₂ at a flow rate of 10 sccm, Ar at a flow rate of 60 sccm, 500 W of plasma power, 80 W of bias power, a wafer temperature of 25 degrees Celsius, and a pressure of 5 mTorr. Such LTPE process forms in-situ the top electrode 230 having the sidewalls 232 that are tapered off at an angle that is not greater than about 750 (e.g., about 70-750) and provides etch selectivity of Ta/TaN (layer 204) over NiFe or CoFe (layer 206) of at least 5:1, as well as etch selectivity of Ta/TaN over photoresist (mask 222) of about 3:1.

At step 108, the photoresist mask 222 is removed, or stripped, thus leaving the structure (i.e., top electrode 230) having a tapered profile on the free magnetic layer 206 (FIG. 2D). Step 108 generally performs a photoresist stripping process that uses a plasma generated from a gas comprising oxygen (O₂). During stripping the mask 222, step 108 may use the top electrode 230 as a stop layer. One such photoresist stripping process is disclosed in U.S. patent application Ser. No. 10/218,244, filed Aug. 12, 2002.

Step 108 can be performed using, e.g., a remote plasma reactor, such as the Advanced Strip and Passivation (ASP) reactor or the AXIOME reactor of the Centura® platform. Alternatively, step 108 can be performed using the DPS reactor.

The ASP reactor is a microwave downstream plasma reactor in which the plasma is confined such that only reactive neutrals are allowed to enter a reaction volume of the process chamber. The wafer backside may be heated (e.g., radiantly, by quartz halogen lamps) or cooled (e.g., providing an inert gas, such as helium, to backside of the wafer) to maintain the wafer temperature between 20 to 400 degrees Celsius. The AXIOM® reactor is described in detail in U.S. patent application Ser. No. 10/264,664, filed Oct. 4, 2002 (Attorney docket number 6094), which is herein incorporated by reference.

At optional step 110, the free magnetic layer 206, as well as other layers of the MRAM film stack 210 (i.e., the tunnel layer 208, multi-layer magnetic stack 210, bottom electrode layer 214, and barrier layer 216), may be etched using the Ta/TaN top electrode 230 as an etch mask (FIG. 2E). As discussed above in reference to FIGS. 2C and 2D, the top electrode 230 has the sidewalls 232 that are sloped at the angle 234 that is not greater than 75°. When used as the etch mask, the top electrode 230 reduces the amount of post-etch conductive residues that are produced on the sides of the MRAM film stack 210 being etched. Examples of etch processes that may be used to etch the underlying layers of the MRAM film stack 210 are disclosed, e.g., in U.S. patent application Ser. No. 10/218,244, filed Aug. 12, 2002 and Ser. No. 10/231,620, filed Aug. 29, 2002.

At step 112, the method 100 ends.

FIG. 3 depicts a schematic diagram of the exemplary Decoupled Plasma Source (DPS) etch reactor 300 that may be used to practice portions of the invention. The DPS reactor is available from Applied Materials, Inc. of Santa Clara, Calif.

The reactor 300 comprises a process chamber 310 having a wafer support pedestal 316 within a conductive body (wall) 330, and a controller 340.

The support pedestal (cathode) 316 is coupled, through a first matching network 324, to a biasing power source 322. The biasing source 322 generally is a source of up to 500 W at a frequency of approximately 13.56 MHz that is capable of producing either continuous or pulsed power. In other embodiments, the source 322 may be a DC or pulsed DC source. The chamber 310 is supplied with a dome-shaped dielectric ceiling 320. Other modifications of the chamber 310 may have other types of ceilings, e.g., a substantially flat ceiling. Above the ceiling 320 is disposed an inductive coil antenna 312. The antenna 312 is coupled, through a second matching network 319, to a plasma power source 318. The plasma source 318 typically is capable of producing up to 3000 W at a tunable frequency in a range from 50 kHz to 13.56 MHz. Typically, the wall 330 is coupled to an electrical ground 334.

A controller 340 comprises a central processing unit (CPU) 344, a memory 342, and support circuits 346 for the CPU 344 and facilitates control of the components of the DPS etch process chamber 310 and, as such, of the etch process, as discussed below in further detail.

In operation, a semiconductor wafer 314 is placed on the pedestal 316 and process gases are supplied from a gas panel 338 through entry ports 326 and form a gaseous mixture 350. The gaseous mixture 350 is ignited into a plasma 355 in the chamber 310 by applying power from the plasma and bias sources 318 and 322 to the antenna 312 and the cathode 316, respectively. The pressure within the interior of the chamber 310 is controlled using a throttle valve 327 and a vacuum pump 336. The temperature of the chamber wall 330 is controlled using liquid-containing conduits (not shown) that run through the wall 330.

The temperature of the wafer 314 is controlled by stabilizing a temperature of the support pedestal 316. In one embodiment, the helium gas from a gas source 348 is provided via a gas conduit 349 to channels formed by the back of the wafer 314 and grooves (not shown) in the pedestal surface. The helium gas is used to facilitate heat transfer between the pedestal 316 and the wafer 314. During the processing, the pedestal 316 may be heated by a resistive heater (not shown) within the pedestal to a steady state temperature and then the helium gas facilitates uniform heating of the wafer 314. Using such thermal control, the wafer 314 is maintained at a temperature of between 0 and 500 degrees Celsius.

Those skilled in the art will understand that other forms of etch chambers may be used to practice the invention, including chambers with remote plasma sources, microwave plasma chambers, electron cyclotron resonance (ECR) plasma chambers, and the like.

To facilitate control of the process chamber 310 as described above, the controller 340 may be one of any form of general-purpose computer processor that can be used in an industrial setting for controlling various chambers and sub-processors. The memory, or computer-readable medium, 342 of the CPU 344 may be one or more of readily available memory such as random access memory (RAM), read only memory (ROM), floppy disk, hard disk, or any other form of digital storage, local or remote. The support circuits 346 are coupled to the CPU 344 for supporting the processor in a conventional manner. These circuits include cache, power supplies, clock circuits, input/output circuitry and subsystems, and the like. The inventive method is generally stored in the memory 342 as a software routine. The software routine may also be stored and/or executed by a second CPU (not shown) that is remotely located from the hardware being controlled by the CPU 344.

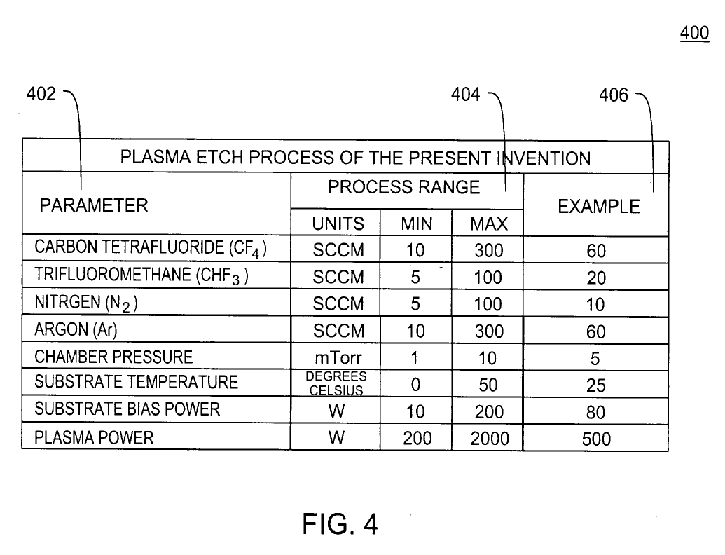

FIG. 4 presents a table 400 summarizing the process parameters of the LTPE process through which one can practice the invention using the DPS reactor. The process parameters for one embodiment of the invention presented above are summarized in column 402. The process ranges are presented in column 404. Exemplary process parameters for etching the Ta/TaN top electrode layer 204 are presented in column 406. It should be understood, however, that the use of a different plasma etch reactor may necessitate different process parameter values and ranges.

The invention may be practiced using other semiconductor wafer processing systems wherein the processing parameters may be adjusted to achieve acceptable characteristics by those skilled in the arts by utilizing the teachings disclosed herein without departing from the spirit of the invention.

Although the forgoing discussion referred to fabrication of the MRAM device, fabrication of the other devices and structures that are used in the integrated circuits can benefit from the invention.

While foregoing is directed to the illustrative embodiment of the present invention, other and further embodiments of the invention may be devised without departing from the basic scope thereof, and the scope thereof is determined by the claims that follow.

What is claimed is:

1. A method of etching a metallic material to form a structure having a tapered profile, comprising:
supplying a substrate comprising a metallic material layer;
forming a patterned etch mask on the material layer;
etching the material layer at a substrate temperature of less than about 50° C. using a gas comprising CF₄, CHF₃, and N₂; and
removing the etch mask.

2. The method of claim 1 wherein the material layer comprises at least one of Ta and TaN.

3. The method of claim 1 wherein the gas further comprises a diluent gas.

4. The method of claim 3 wherein the diluent gas is Ar.

5. The method of claim 1 wherein the etching step further comprises:
providing CF₄ and CHF₃ at a flow ratio CF₄: CHF₃ in a range from 1:10 to 60:1.

6. The method of claim 1 wherein the etching step further comprises:
providing CHF₃ and N₂ at a flow ratio CHF₃:N₂ in a range from 1:20 to 20:1.

7. The method of claim 1 wherein the etching step further comprises:
maintaining the substrate temperature in a range from about 0 to not greater than 50 degrees Celsius.

8. The method of claim 1 wherein the etch step further comprises:
providing CF₄ and CHF₃ at a flow ratio CF₄:CHF₃ in a range from 1:10 to 60:1;
providing CHF₃ and N₂ at a flow ratio CHF₃:N₂ in a range from 1:20 to 20:1;
maintaining the substrate at the temperature that is not greater than about 50 degrees Celsius;
applying plasma power of about 200 to 2000 W;
applying the substrate bias power of about 10 to 200 W; and maintaining a gas pressure in the process chamber in a range from 1 to 10 mTorr.

9. A computer-readable medium containing software that when executed by a computer causes a semiconductor wafer processing system to fabricate a structure having a tapered profile using a method, comprising:
supplying a substrate comprising a metallic material layer;
forming a patterned etch mask on the material layer;
etching the material layer at a substrate temperature of less than about 50° C. using a gas comprising CF₄, CHF₃, and N₂; and
removing the etch mask.

10. The computer-readable medium of claim 9 wherein the material layer comprises at least one of Ta and TaN.

11. The computer-readable medium of claim 9 wherein the gas further comprises a diluent gas.

12. The computer-readable medium of claim 11 wherein the diluent gas is Ar.

13. The computer-readable medium of claim 9 wherein the etching step further comprises:
providing CF₄ and CHF₃ at a flow ratio CF₄: CHF₃ in a range from 1:10 to 60:1.

14. The computer-readable medium of claim 9 wherein the etching step further comprises:
providing CHF₃ and N₂ at a flow ratio CHF₃:N₂ in a range from 1:20 to 20:1.

15. The computer-readable medium of claim 9 wherein the etching step further comprises:
maintaining the substrate temperature in a range from about 0 to not greater than 50 degrees Celsius.

16. The computer-readable medium of claim 9 wherein the etch step further comprises:
providing CF₄ and CHF₃ at a flow ratio CF₄:CHF₃ in a range from 1:10 to 60:1;
providing CHF₃ and N₂ at a flow ratio CHF₃:N₂ in a range from 1:20 to 20:1;
maintaining the substrate at the temperature that is not greater than about 50 degrees Celsius;
applying plasma power of about 200 to 2000 W;
applying the substrate bias power of about 10 to 200 W; and
maintaining a gas pressure in the process chamber in a range from 1 to 10 mTorr.
